(19) United States
(12) Patent Application Publication
(10) Pub. No.: US 2008/0309389 A1
(43) Pub. Date: Dec. 18, 2008

(54) SYSTEM FOR PREVENTING SHOPPING CART PUSH-OUT THEFT

(76) Inventors: John R. French, San Diego, CA (US); Joseph F. Nebolon, Del Mar, CA (US); Robert M. Harling, Valley Center, CA (US); Dante A. Galli, Vista, CA (US)

Correspondence Address: NEIL K. NYDEGGER;NYDEGGER & ASSOCIATES, 348 Oliver Street, San Diego, CA, 92103, US

(21) Appl. No.: 11/763,710

(22) Filed: Jun. 15, 2007

(51) Int. Cl. H03K 5/01; B62D 39/00

(52) U.S. Cl. 327/167; 280/33.992

(57) ABSTRACT

A system and method for preventing push-out theft includes a network of electronic devices that are collectively operable in either a “safe restart” mode” or in an “operational” mode. The network is installed in a shopping area and prevents shopping cart removal from the area when in the “operational” mode. It does this by initially issuing egress permits to every shopping cart. The network then selectively removes egress permits when a shopping cart enters a selected section of the shopping area. Another egress permit is issued when the shopping cart successfully passes a cashier location. Otherwise, a sentry beacon will disable a shopping cart with no egress permit, before it can leave the shopping area. The network defaults to a permit issuing mode whenever a component of the system becomes inoperable.

### FIELD OF THE INVENTION

The present invention pertains generally to a system and to a method for preventing the loss of inventory items from the premises of a commercial enterprise. More particularly, the present invention pertains to systems and methods that are employed to prevent the unauthorized removal of inventory items after they have been loaded into a shopping cart (i.e. “push out” theft). The present invention is particularly, but not exclusively, useful as a system and a method that selectively activates and deactivates a locking mechanism pursuant to an electronic permit for the egress of a shopping cart from a defined shopping area.

### BACKGROUND OF THE INVENTION

Inventory “shrink” is a significant source of loss for retail operators, totaling as much as four percent of total sales, depending on the retail channel. One substantial component of “shrink” for retailers that provide shopping carts for customers is frequently referred to as “push-out”. Specifically, “push-out” occurs when a customer loads a cart or trolley with valuable goods and exits the store without paying. Retailers report that push-out is a growing concern and is becoming increasingly organized and costly.

Along with the need for preventing push-out theft, it is also extremely important that good, honest customers not be unnecessarily inconvenienced while shopping. In particular, customers should not be somehow prevented from performing their shopping activities because of an electronic or mechanical malfunction in a security system. On balance, the risk of experiencing a push-out theft during a security system malfunction may be acceptable, when compared with the aggravation that will most certainly be caused by an unfounded interruption of normal activity in a shopping area.

In light of the above, it is an object of the present invention to provide a system and method for preventing unauthorized removal of a shopping cart from a defined area. Another object of the present invention is to provide a network for preventing push-out theft that defaults to a safe mode wherein all shopping carts have unfettered movement within a shopping area whenever an electronic component (device) of the network is inoperable. Still another object of the present invention is to provide a system and method for preventing an unauthorized removal of a shopping cart from a shopping area that is easy to install, is simple to use and is comparatively cost effective.

### SUMMARY OF THE INVENTION

The present invention provides a two-tier system for the purpose of preventing “push-out” theft of inventory items as they are being carried from a shopping area in a shopping cart. The first tier involves the installation and employment of electronic devices that will selectively prevent movement of individual shopping carts in egress from the premises of a commercial enterprise. The second tier provides for system oversight and involves monitoring and management of the first tier either on-site or off-site.

A plurality of electronic devices is employed in the first tier of the system to create an electronic environment (i.e. a network). As envisioned for the present invention, the network will be installed in a shopping area on the premises of a commercial enterprise to provide for the selective activation of locking devices that are individually mounted on respective shopping carts. This activation and deactivation involves the issuance and revocation of egress permits for each shopping cart. And, in accordance with the present invention, the activation of a locking device occurs only when the shopping cart is being removed from the premises, without an egress permit (e.g. without payment for items that have been collected and are being carried in the shopping cart).

In the second tier, the operation of the network in the first tier is monitored. This is done by a central operator (i.e. a computer) that can be located either on-site or off-site. Further, shopping cart activity that is detected by the network may also be monitored by the central operator. For the present invention, a plurality of networks (i.e. electronic environments) can be connected to the same central operator at the second tier. Stated differently, although the system includes only one central operator, each commercial enterprise in the system will have its own separate first tier network.

The network that is created for the first tier of the present invention includes a network integrator. This network integrator provides security for the network and establishes the logic for the network of the electronic environment. It is centrally located, and is a so-called Full Function Device (FFD). For purposes of the present invention, an FFD is a device that is capable of routing data packets over-the-air (OTA) to a recipient device. Importantly, the network integrator gives the network its network identification (ID), and it stores information that is received from every other device in the network. This is done in a “network information table” on a non-volatile memory. In addition to the network integrator, other FFDs (i.e. “routers” or “repeaters”) can be installed on the premises as required. Each FFD, however, must be within communicating distance of at least one other FFD, and each FFD must be able to communicate (albeit sometimes indirectly through another FFD) with the network integrator.

In addition to the FFDs, the present invention envisions also using Reduced Function Devices (RFDs). Like FFDs, the RFDs are electronic devices capable of transmitting data packets OTA to the network integrator (either directly or through FFDs). Unlike the FFDs, however, RFDs do not have a routing capability. Thus, it will be appreciated that FFDs establish the network's operational backbone. In any event, it is important for the present invention that all devices must communicate with the network integrator, regardless whether such communication is direct, or through an FFD.

As indicated above, each first tier network is connected to the second tier. Specifically, this is accomplished by either an Ethernet or phone modem connection via a web portal. For the present invention, it is the web portal that connects the first tier with the central operator at the second tier. Through the web portal, the central operator at the second tier is able to monitor the first tier and prepare appropriate reports.

For the implementation of the present invention, the entire network will operate in either of two modes that are selected by the network integrator. One is a “safe restart” mode and the other is an “operational” mode. Further, depending on the particular network mode that is in effect, the FFDs and RFDs in the network may be configured to perform different beacon functions. In the “safe restart” mode, however, all beacons default to a permit issuing function. On the other hand, when the system is in its “operational” mode, the beacons can become functionally distinct. Specifically, in the operational mode some beacons will function as permit issue beacons. These permit issue beacons are typically located at cashier locations in the shopping area, and they issue permits to shopping carts that pass the cashier location. Other beacons will function as permit remover beacons in the network operational mode. These beacons are selectively located in the shopping area and are used to remove permits from shopping carts. Still other beacons will function as sentry beacons that will activate a caster lock on a shopping cart. Specifically, this is done when the cart has no issued egress permit, and is operated in the vicinity of the sentry beacon with the intent of removing the cart from the shopping area.

In overview, during an operation of a network in the system and method of the present invention, the network issues permits for the egress of shopping carts from the premises. Specifically, in the “safe restart” mode, all beacons in the network perform the permit issuing function. In the “operational mode”, however, certain beacons change their function to become permit removal beacons and the network can then selectively remove egress permits from shopping carts. Subsequently, a shopping cart without an egress permit will be disabled by a sentry beacon and cannot be removed from the premises until it has been issued another permit. An important safety feature of the present invention is that the “safe restart” mode is the “default” mode for the entire system. Stated differently, whenever any device in the network becomes inoperable (i.e. cannot communicate with the network integrator) the network defaults and every beacon gives every shopping cart an egress permit.

By way of example, consider the ingress and egress of a single shopping cart into and out of a shopping area that is serviced by a system of the present invention. As a shopping cart is retrieved from a shopping cart collection point it will have an egress permit. Subsequently, as the shopping cart enters selected sections of the shopping area, a permit removal beacon may remove the egress permit from the cart. Nevertheless, within the shopping area, the cart is still free to move about as the consumer picks up items and places them into the shopping cart for subsequent purchase. At a check out stand, once items in the shopping cart have been properly purchased, a permit issue beacon issues a new egress permit to the shopping cart. The shopping cart can then be removed from the shopping area and past sentry beacons, without incident. Once unloaded, the shopping cart is returned to the shopping cart collection point. On the other hand, if a cart does not pass a cashier location to receive an egress permit, a strategically located sentry beacon will then interact with a locking caster on the shopping cart. Specifically, after the shopping cart has left the shopping area, the sentry beacon will cause the locking caster to activate, and thereby prevent further movement of the shopping cart. Recall, the shopping cart will normally have an issued egress permit that was issued either while the network was in its “safe restart” mode (e.g. as a “default”), or at a cashier location after the contents of the shopping cart have been paid for.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is an organizational chart of the system of the present invention;

FIG. 2 is a suggested layout for the electronic devices that are incorporated into the system of the present invention; and

FIG. 3 is representative schematic drawing of shopping cart traffic through a shopping area as envisioned for the present invention.

### DESCRIPTION OF THE PREFERRED EMBODIMENTS

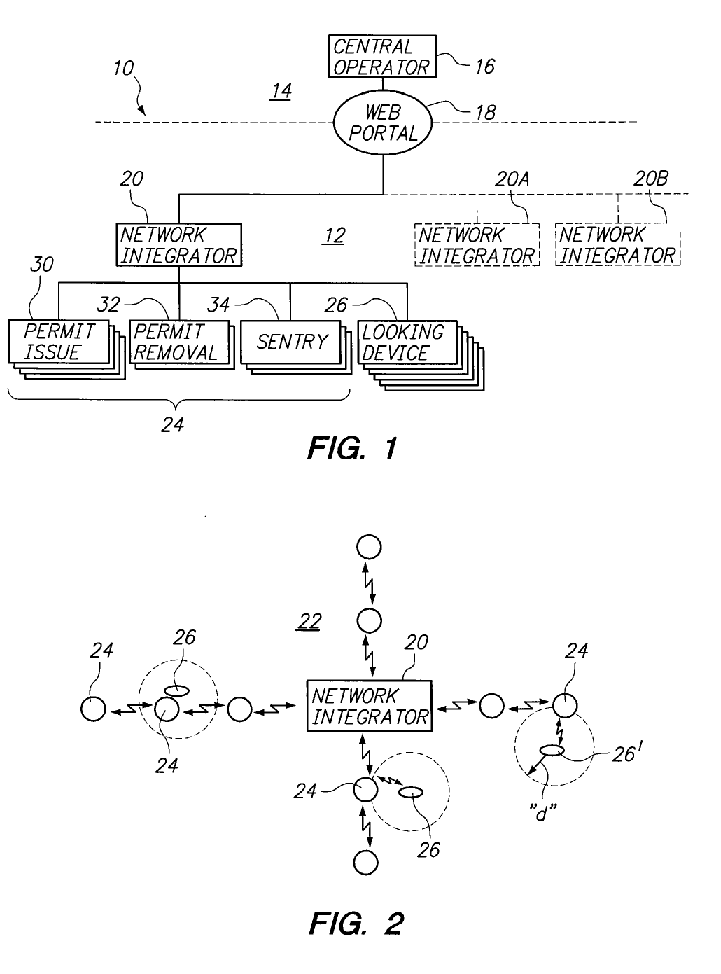

Referring initially to FIG. 1, a system in accordance with the present invention is presented as an organizational chart and is generally designated 10. As shown, the system 10 includes at least one network 12 and a single oversight controller 14. More particularly the oversight controller 14 is shown to include a central operator 16 whose function is to monitor and manage the network 12. For purposes of the present invention, the central operator 16 will preferably be a computer(s) and the central operator 16 may either be co-located with the network 12, or located off-site in a separate facility. In any event, the central operator 16 will communicate with the network 12 via a web portal 18 (e.g. Ethernet or phone modem connection). Further, the central operator 16 will be in communication with a network integrator 20 that is located in the network 12.

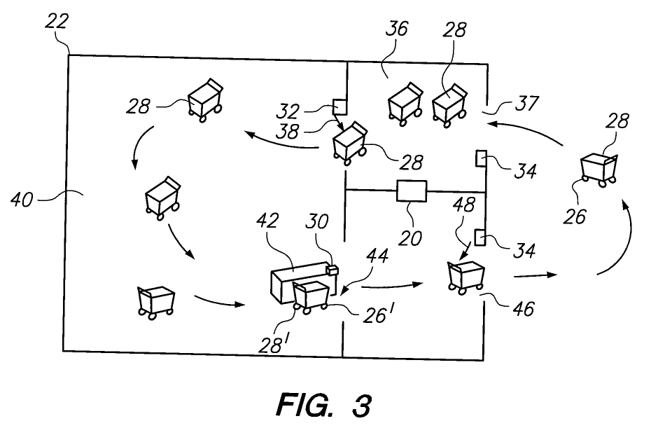

Still referring to FIG. 1, it will be seen that the system 10 can accommodate a plurality of network integrators 20 (network integrators 20a and 20b are only exemplary). As intended for the system 10 of the present invention, each network integrator 20 will be located on the premises of a separate commercial enterprise. And, the network integrator 20 will be centrally positioned in a shopping area 22 of the commercial enterprise (see FIGS. 2 and 3). FIG. 1 also shows that, within each network 12 there is one network integrator 20 that interacts with several other electronic devices. Specifically, in addition to a network integrator 20, the network 12 will include a plurality of beacons 24, as well as a plurality of locking devices 26. As disclosed in more detail below, the beacons 24 will be strategically located within the shopping area 22, and the locking devices 26 will be respectively mounted on a shopping cart 28 (see FIG. 3). As envisioned for the present invention, the beacons 24 and the locking devices 26 are electronic devices that may either be so-called Full Function Devices (FFD) that can act as a “repeater”/“router” for over-the-air transmissions, or (for reasons of economy) they may be Reduced Function Devices (RFD) that do not have a forward transmission capability.

In accordance with the present invention, individual beacons 24 may be required to perform different functions. Accordingly, some beacons 24 must be capable of switching between either of two different functions. Switching of beacon functions is controlled by the network integrator 20, and is required to regulate the issuance and removal of permits for movement of individual shopping carts 28 through the shopping area 22. For the system 10, this involves the issue and removal of egress permits that can be electronically placed on the locking device 26 of a shopping cart 28. With this in mind, it will be appreciated that some of the beacons 24 need to function as permit issue beacons 30. Others will selectively function as permit removal beacons 32. And, other beacons 24 will selectively function as sentry beacons 34. Importantly, the permit removal beacons 32 and the sentry beacons 34 can sometimes also function as permit issue beacons 30.

For the system 10, the installation of a network 12 in a shopping area 22 on the premises of a commercial enterprise can be configured in several ways. FIG. 2 shows an exemplary installation wherein the network integrator 20 is centrally located in the shopping area 22. Generally, beacons 24 can then be arrayed throughout the shopping area 22 as required. The orthogonal orientation of beacons 24 in FIG. 2 is only exemplary. Regardless of their orientation, however, all of the beacons 24 in the network 12 must somehow, directly or indirectly, be in communication with the network integrator 20. For this reason, FFD type beacons 24 (i.e. “routers”) need to be appropriately installed to establish a so-called “backbone” for the network 12. Further, within the area 40, each locking device 26 must be able to communicate with a beacon 24. This is particularly important because the locking devices 26 will be mobile within the shopping area 22, and the transmission distance “d” of a locking device 26 may be limited (e.g. see locking device 26' in FIG. 2). Making certain that all electronic devices are operable (i.e. network integrator 20, beacons 24 and locking devices 26), and functioning properly is an important function of the system 10.

Operationally, under the control of the network integrator 20, the network 12 can be placed in either a “safe restart” mode, or an “operational” mode. Importantly, when the network 12 is placed in the “safe restart” mode, all beacons 24 function as a permit issue beacon 30. On the other hand, in the “operational” mode, each beacon 24 reverts to a special status and, depending on how it is programmed, may function as a permit issue beacon 30, a permit removal beacon 32, or a sentry beacon 34. In “default”, the network 12 will go into its “safe restart” mode.

By way of example, refer to FIG. 3 for the illustration of a shopping cycle for a shopping cart 28 as envisioned by the present invention. Initially, a customer (not shown) will normally retrieve a shopping cart 28 from a cart collection area 36 that is located on the premises of a commercial enterprise. Typically, the cart collection area 36 will be located somewhere near an entrance 37. At this point, the shopping cart 28 should already have been issued an egress permit. This most likely will result because, either the shopping cart 28 was returned to the cart collection area 36 with an egress permit already issued, or the system 10 had been recently operated in the “safe restart” mode. With an egress pass, however obtained, the shopping cart 28 can then be moved from the collection area 36 and into the shopping area 40. When the system 10 is in its “operational” mode”, the shopping cart 28 passes a permit removal beacon 32 as it enters the shopping area 40, and its egress permit is removed by a transmission 38 from the permit removal beacon 32.

With the permit removed from its locking device 26, the shopping cart 28 is free to move within the shopping area 40. While in the shopping area 40 the customer is able to place items for purchase in the shopping cart 28 as desired. The shopping cart 28 is then moved to a cashier location 42 where the items can be purchased (i.e. the location for cart 28' shown in FIG. 3). Upon completion of the transaction, a permit issue beacon 30 at the cashier location 42 will issue another egress permit via a transmission 44. The shopping cart 28 can then be moved past the sentry beacon 34 at exit 46. Otherwise, without an egress permit on its locking device 26, the shopping cart 28 will be disabled by a transmission 48 from the sentry beacon 34. Normally, however, the shopping cart 28 will have an egress permit and can pass unencumbered through the exit 46. After items have been unloaded form the shopping cart 28, it is returned to the cart collection area 36 for use by another customer.

While the particular System for Preventing Shopping Cart Push-Out Theft as herein shown and disclosed in detail is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A system for preventing unauthorized removal of a shopping cart from a defined area which comprises:
a plurality of electronic devices arrayed in the defined area as a network;
a means for selectively operating the network in a “safe restart” mode and an “operational” mode; and
a locking device mounted on the shopping cart, wherein the locking device is responsive to the network in its operational mode to allow shopping cart removal from the defined area after the shopping cart has been issued an egress permit by the network, and to otherwise prevent egress of the shopping cart.

2. A system as recited in claim 1 further comprising:
a web portal; and
a central operator, wherein the central operator is connected to the network via the web portal to provide oversight for the network and prepare reports of shopping cart activity in the defined area.

3. A system as recited in claim 2 wherein the central operator is a computer.

4. A system as recited in claim 1 wherein the plurality of electronic devices comprises:
a network integrator for establishing a network identification, for providing network security, and for storing information from the network in an information network table;
at least one permit issue beacon for selectively issuing egress permits to a shopping cart;
at least one permit remover beacon for removing permits from a shopping cart when the network is in its operational mode; and
at least one sentry beacon for activating the locking device on a shopping cart when an egress permit is absent therefrom.

5. A system as recited in claim 4 wherein the defined area is a shopping area of a commercial enterprise with the shopping area having an exit and a cashier location within the shopping area, and wherein a sentry beacon is positioned near the exit, a permit remover beacon is positioned within the shopping area, and a permit issue beacon is positioned at the cashier location.

6. A system as recited in claim 4 wherein the “safe/restart” mode is a “default” mode for all electronic devices in the network.

7. A system as recited in claim 6 wherein the network integrator selectively activates the “operational” mode for the network when all electronic devices in the network are operable, and automatically initiates the “default” mode when any electronic device in the network is inoperable.

8. A system as recited in claim 4 wherein the network integrator, the permit remover beacon and the sentry beacon are each a full function device.

9. A system as recited in claim 8 wherein the permit issue beacon is a reduced function device.

10. A theft prevention system which comprises:
a network including a plurality of electronic devices collectively installed to cover a defined area, wherein the network is operable in a first mode and, alternatively, in a second mode;
a means for selectively switching the network between its first mode and its second mode;
a means for preventing removal of a shopping cart from the defined area; and
an actuator means for selectively energizing the preventing means when the network is in its first mode, and for ignoring the preventing means when the network is in its second mode.

11. A system as recited in claim 10 wherein the preventing means is a locking device mounted on the shopping cart, and the actuator means is a sentry beacon positioned at an exit from the defined area.

12. A system as recited in claim 11 wherein the switching means is a network integrator to establish the first mode for the network when all electronic devices in the network are operable, and to automatically establish the second mode when any electronic device in the network is inoperable.

13. A system as recited in claim 12 wherein the network integrator establishes a network identification for the network and stores information from the network in an information network table.

14. A system as recited in claim 12 wherein the actuator means is operationally responsive to an egress permit, and the network further comprises:
at least one permit issue beacon for selectively issuing egress permits to a shopping cart to avoid interaction by the shopping cart with the preventing means when the network is in its first mode; and
at least one permit remover beacon for removing an egress permit from the shopping cart for interaction of the actuator means with the preventing means when the network is in its first mode.

15. A system as recited in claim 10 further comprising:
a web portal; and
a central operator, wherein the central operator is connected to the network via the web portal to provide oversight for the network.

16. A method for preventing unauthorized removal of a shopping cart from a defined area which comprises the steps of:
mounting a locking device on the shopping cart;
installing a plurality of electronic devices arrayed in the defined area as a network;
selectively switching the network between a first mode and a second mode; and
preventing the shopping cart from departing the defined area by energizing the locking device when the network is in its first mode, and the shopping cart fails to have an egress permit.

17. A method as recited in claim 16 further comprising the steps of:
removing an egress permit from the shopping cart when it enters a selected section of the defined area; and
issuing an egress permit to a shopping cart before it departs from the defined area.

18. A method as recited in claim 17 wherein the issuing step is accomplished by all electronic devices in the system when the network is in its second mode and by only selected devices in the system when the network is in its first mode.

19. A method as recited in claim 18 wherein the switching step is accomplished to selectively establish the first mode for the network when all electronic devices in the network are operable, and to automatically establish the second mode for the network when any electronic device in the network is inoperable.

20. A method as recited in claim 19 further comprising the step of monitoring the network operation with a computer.
